(19) United States
(12) Patent Application Publication
(10) Pub. No.: US 2025/0231493 A1
(43) Pub. Date: Jul. 17, 2025

(54) METHOD FOR OPERATING AN OPTICAL COMPONENT, AND OPTICAL COMPONENT

(71) Applicant: Carl Zeiss SMT GmbH, Oberkochen (DE)

(72) Inventors: Ralf NOLTEMEYER, Herrenberg (DE); Steffen LINSENMAYER, Dettingen unter Teck (DE); Wenqing LIU, Weil der Stadt (DE)

(21) Appl. No.: 19/171,128

(22) Filed: Apr. 4, 2025

Related U.S. Application Data
(63) Continuation of application No. PCT/EP2023/079432, filed on Oct. 23, 2023.

(30) Foreign Application Priority Data
Oct. 26, 2022 (DE) 10 2022 211 335.7

(51) Int. Cl. G03F 7/00

(52) U.S. Cl. CPC G03F 7/70233; G03F 7/70266

(57) ABSTRACT

A method of operating an optical component having a mirror element, a substrate for carrying the mirror element, an actuator device for tilting the mirror element about one or two tilt axes, having a plurality of active actuator electrodes and one or more passive actuator electrodes, and a sensor device having a sensor electrode structure for detecting a tilt angle of the mirror element based on changes in capacitance, having a plurality of active sensor electrodes and a plurality of passive sensor electrodes, wherein the method comprises: generating a first voltage between a first portion of the active actuator electrodes and the passive actuator electrodes; and generating a second voltage between a second portion of the active actuator electrodes and the passive actuator electrodes. A respective potential different from a reference potential is applied to the one or more passive actuator electrodes by a voltage source with the reference potential.

### CROSS-REFERENCE TO RELATED APPLICATIONS

The present application is a continuation of, and claims benefit under 35 USC 120 to, international application No. PCT/EP2023/079432, filed Aug. 7, 2023, which claims benefit under 35 USC 119 of German Application No. 10 2022 211 335.7, filed Oct. 26, 2022. The entire disclosure of each of these applications is incorporated by reference herein.

### FIELD

The disclosure relates to a method of operating an optical component having a mirror element, a substrate for carrying the mirror element, an actuator device for tilting the mirror element and a sensor device having a sensor electrode structure for detecting a tilt angle of the mirror element based on changes in capacitance. The disclosure also relates to an optical component and to an optical apparatus having such an optical component. Moreover, the disclosure relates to an illumination optical unit and an illumination system for a projection exposure apparatus, and a projection exposure apparatus.

### BACKGROUND

Depending on the application, micromirrors may be used in different applications, such as for example smartphone projectors, head-up displays, barcode readers, etc.

For EUV lithography systems, adjustable optical paths up to the reticle, also called a mask, which are able to be implemented by a micromirror array in the optical path, are often desirable.

The micromirrors may be provided with a Bragg coating that reflects the central wavelengths well. Wavelengths outside the reflection range can be absorbed and generate heat in the micromirror, which can be dissipated in a targeted manner with the lowest possible temperature resistance.

The positional accuracy of the micromirror can depend on how well the system for positioning the micromirrors works. This depends for example on manufacturing tolerances, temperature stability in combination with temperature variance and long-term stability in combination with product lifetime or the times at which the device is recalibrated.

Document DE 10 2015 204 874 A1 relates to an actuator device for tilting a mirror element.

Document DE 10 2016 213 026 A1 relates to a sensor device for detecting a tilt angle of a mirror element.

The two documents each describe an optical component that comprises an actuator device for tilting a mirror element with two tilting degrees of freedom and a sensor device for detecting a tilt angle of the mirror element. The actuator device comprises an actuator electrode structure having actuator electrodes that are in the form of comb electrodes and form a direct drive for pivoting the mirror element. The sensor device comprises a sensor electrode structure having sensor electrodes that are likewise in the form of comb electrodes. The optical component furthermore comprises a gimbal flexure for mounting the mirror element, wherein the flexure has flexure springs and defines two tilt axes of the mirror element.

### SUMMARY

A method for operating an optical component is proposed. The optical component comprises a mirror element, a substrate for carrying the mirror element, which may in particular be a micromirror element, an actuator device for tilting the mirror element about one or two tilt axes, having a plurality of active actuator electrodes and one or more passive actuator electrodes. The optical component furthermore comprises a sensor device having a sensor electrode structure for detecting a tilt angle of the mirror element based on changes in capacitance. A tilt angle of the mirror element corresponds to a polar angle of a spherical coordinate system. The tilt angle may in this case be azimuth-dependent.

The sensor electrode structure in this case comprises a plurality of active sensor electrodes, such as for example two, four, six or more, and a plurality of passive sensor electrodes, such as for example two, four, six or more. The active and passive sensor electrodes can be in the form of comb electrodes. The number of active sensor electrodes can be equal to the number of passive sensor electrodes. The number of active sensor electrodes may also be one higher or lower than the number of passive sensor electrodes. Optionally, the passive sensor electrodes are each assigned to an active sensor electrode. The active sensor electrodes in this case comprise sensor transmitter electrodes and sensor receiver electrodes that are each optionally in the form of comb electrodes. The sensor transmitter electrodes, in order to detect the tilt angle of the mirror element, may be subjected to an AC voltage.

According to the disclosure, a method comprises generating a first voltage between a first portion of the active actuator electrodes and the one or more passive actuator electrodes and generating a second voltage between a second portion of the active actuator electrodes and the one or more passive actuator electrodes, wherein a respective potential is applied to the one or more passive actuator electrodes, which potential is different from a reference potential, for example a ground potential, of a voltage source that is used to generate these potentials. The potentials of the one or more passive actuator electrodes can be identical, that is to say they have a common potential. The reference potential is connected to the voltage source and constitutes the reference potential for the potentials applied to the one or more passive actuator electrodes. Optionally, the potentials applied to the one or more passive actuator electrodes are also different from a second potential of the passive sensor electrodes, wherein each of the passive sensor electrodes particularly optionally has the reference potential and/or a ground potential. The latter can help make it possible to reduce noise in signals from the sensor device.

The plurality of active actuator electrodes and the one or more passive actuator electrodes are configured to exert electrostatic force so as to tilt the mirror element. The active actuator electrodes and the at least one passive actuator electrode can be in the form of comb electrodes. All of the active actuator electrodes are furthermore optionally arranged along a common plane, which is also referred to as actuator plane. This means that one end of each active actuator electrode is arranged in this common plane. The individual active actuator electrodes may in this case have different dimensions, in particular different lengths. The actuator device may form a direct drive for tilting the mirror element. The first and the second portion of the active actuator electrodes are located here on different sides of one of the one or two tilt axes. The two voltages (the first voltage and the second voltage) are selected to be different in order to generate a torque about the corresponding tilt axis. Accordingly, the passive actuator electrodes, in the case of a plurality of passive actuator electrodes, may also be divided into a first and a second portion, which are located on different side of the tilt axis. A direct drive should be understood here to mean a drive in which the actuator device is able to exert a force directly on the mirror to be displaced. In particular, no force transmission mechanism is required. In other words, the drive is force-transmission-mechanism-free.

Applying one or more potentials different from the reference potential to the passive actuator electrodes makes it possible to increase the torque generated by the different voltages. This is determined as:

$${M}_{12} = \frac{1}{2} \frac{\partial {C}_{A 1}}{\partial ϑ} {( {U}_{1} - {U}_{N 1} )}^{2} - \frac{1}{2} \frac{\partial {C}_{A 1}}{\partial ϑ} {( {U}_{2} - {U}_{N 2} )}^{2}$$

In this case, U_{N1} is the potential applied to a first portion of the passive actuator electrodes, U_{N2} accordingly denotes the potential applied to a second portion of the passive actuator electrodes, each with respect to the reference potential. Or in the case of a single passive actuator electrode, a single common potential U_{N}=U_{N1}=U_{N2} can be involved here. The variables U₁, respectively U₂, accordingly denote the potentials of the first, respectively second portion of the active actuator electrodes, likewise with respect to the reference potential. The factors ∂C_{Ai}/∂θ, i=1, 2 are the motor constants with respect to the corresponding portion of the actuator electrodes that has a capacitance of C_{Ai}, which is dependent on the tilt angle θ. The motor constants thus describe the magnitude of the change in capacitance C_{Ai} as a function of the tilt angle θ.

Active actuator electrodes should be understood here to mean the actuator electrodes that, in order to tilt the mirror element, are subjected to a variable, for example controllable, for example regulatable potential, that is to say are used primarily to control the mirror element. The active actuator electrodes are accordingly typically connected to a control unit for controlling the corresponding actuator device. Actuator electrodes that are subjected to a fixed, that is to say constant, potential optionally for longer periods than the active actuator electrodes are also referred to as passive actuator electrodes. A change in the potential applied to the passive actuator electrodes may, according to the disclosure, lead to a change in the generated torque about a tilt axis. The passive actuator electrodes may thus be used to support the control of the mirror element. A method according to the disclosure is desirable, for example, when a circuit for generating the potential for the active actuator electrodes that is used for control purposes, that is to say for example a control unit for controlling the corresponding actuator device, is not able to generate a suitably high potential in comparison with the reference potential.

The active actuator electrodes can be attached to the substrate and the one or more passive actuator electrodes are attached to the mirror element. In this case, the active actuator electrodes are also referred to as actuator stator electrodes, while the passive actuator electrodes are also referred to as actuator mirror electrodes.

The active sensor electrodes can be attached to the substrate and the passive sensor electrodes are attached to the mirror element. In this case, the active sensor electrodes are also referred to as sensor stator electrodes, while the passive sensor electrode is also referred to as sensor mirror electrode.

The active sensor electrodes can be arranged along the common plane along which the active actuator electrodes are also arranged. The active sensor electrodes may also have different dimensions, in particular different lengths. The active sensor electrodes can be each assigned to an active actuator electrode.

The number of active sensor electrodes may be equal to the number of active actuator electrodes. By way of example, each active actuator electrode may be assigned to an active sensor electrode. The number of active sensor electrodes may also be different from the number of active actuator electrodes. By way of example, the number of active actuator electrodes may be greater than the number of active sensor electrodes.

The actuator device may be part of a displacement device for displacing the mirror element, or the displacement device itself. The sensor device may likewise be part of the displacement device. The sensor electrode structure may thus be integrated into the actuator electrode structure.

The actuator device may be configured to tilt the mirror element with a single tilting degree of freedom. The mirror element is in this case tilted about a tilt axis. The tilt axis makes it possible to divide the common plane into two sectors, that is to say regions. By way of example, the first portion of the active actuator electrodes may be arranged in the first of the two sectors and the second portion of the active actuator electrodes may be arranged in the second of the two sectors. A corresponding arrangement may be present for the passive actuator electrodes. The active and passive actuator and sensor electrodes may in this case be arranged symmetrically about the tilt axis.

The actuator device can be configured to tilt the mirror element with two tilting degrees of freedom. In this case, the mirror element may be tilted about two tilt axes, which can be oriented perpendicular to one another, simultaneously or in temporal succession. In this case, the two tilt axes make it possible to divide the common plane into four sectors, also referred to as quadrants. The actuator and sensor electrode structure may in this case exhibit radial symmetry. In other words, the actuator or sensor electrodes may be arranged symmetrically about a centre point, which is also referred to as tilt point of the mirror element. Such a design can help make it possible to improve the displacement of the mirror element. Similarly to the case of a single tilt axis, the active and the passive actuator electrodes may be divided into four portions, corresponding to the four quadrants. Four potentials U₁, U₂, U₃, U₄ for the four portions of the active actuator electrodes may be provided in order to generate torques for the two tilt axes. The same applies to the four portions of the passive actuator electrodes; four potentials U_{N1}, U_{N2}, U_{N3}, U_{N4} may be applied here. Or in the case of a single passive actuator electrode, a single common potential U_{N}=U_{N}1=U_{N}2=U_{N}3=U_{N4} can be also involved here.

In the context of this disclosure, a displacement should be understood to mean, in general, a displacement in view of a specific degree of freedom. For example, the displacement of the mirror element may be pivoting, which is also referred to as tilting. In general, the displacement may also comprise linear displacements and/or twisting of the mirror element in a mirror plane. The optical component may in this case comprise a gimbal flexure for mounting the mirror element, wherein the flexure has flexure springs and defines two tilt axes of the mirror element.

For details regarding an actuator device for tilting the mirror element with two tilting degrees of freedom and a sensor device for detecting the tilt angle of the mirror element, reference may be made to DE 10 2015 204 874 A1 and DE 10 2016 213 026 A1, which are hereby incorporated in full into the present application as part thereof.

Optionally, the application of one, optionally each, potential to the one or more passive actuator electrodes is performed only at a certain time and/or in the presence of defined conditions, for example when the first voltage exceeds a first limit value and/or the second voltage exceeds a second limit value. Likewise, one, optionally each, of the potentials applied to the one or more passive actuator electrodes may be changed, for example deactivated or increased or reduced, at a certain time and/or when defined conditions are met, for example when the first voltage exceeds a third limit value and/or the second voltage exceeds a fourth limit value. For example, one, optionally each of the potentials applied to the one or more passive actuator electrodes may be regulated, for example on the basis of one or more setpoint values for one or more voltages between the passive and the active actuator electrodes and/or one or more setpoint values for one or more tilt angles.

A second aspect of the disclosure is the provision of an optical component that is configured to carry out the method according to the disclosure. The optical component in this case comprises a mirror element, a substrate for carrying the mirror element, an actuator device for tilting the mirror element about one or two tilt axes, having a plurality of active actuator electrodes and a plurality of passive actuator electrodes, and a sensor device for detecting a tilt angle of the mirror element.

A method according to the disclosure can be carried out using the optical component proposed according to the disclosure. Accordingly, features described within the scope of the optical component can apply to the method and, conversely, features described within the scope of the method can apply to the optical component. Multiple optical components according to the disclosure may together form a mirror array.

According to a third aspect, what is proposed is an optical apparatus comprising a plurality of optical components according to the disclosure, which can form a mirror array. The optical apparatus furthermore comprises a voltage source for applying one or more potentials to the passive actuator electrodes of the actuator devices of the one or more optical components and a control unit for controlling each of the actuator devices of the one or more optical components by applying potentials to the active actuator electrodes and controlling these potentials, wherein the control unit and the voltage source are connected to a common reference potential, for example a ground potential. Such an apparatus may for example be designed such that different potentials for the passive actuator electrodes may be applied for different optical components. It is thereby possible for example to partially compensate for different spring stiffnesses of a flexure that is used, these possibly being caused for example by production fluctuations.

Furthermore proposed is an illumination optical unit for a projection exposure apparatus for guiding illumination radiation to an object field, which illumination optical unit comprises at least one mirror array according to the disclosure.

Also proposed is an illumination system for a projection exposure apparatus, which illumination system comprises an illumination optical unit according to the disclosure and a radiation source, in particular an EUV radiation source.

Additionally proposed is a microlithographic projection exposure apparatus that comprises an illumination optical unit according to the disclosure and a projection optical unit for projecting a reticle arranged in an object field into an image field.

For details regarding a possible projection exposure apparatus, reference may be made to DE 10 2015 204 874 A1 and DE 10 2016 213 026 A1, which are hereby incorporated in full into the present application as part thereof.

A method proposed according to the disclosure can increase a torque for tilting a mirror element, which torque is generated by an actuator device, by applying potentials that are different from a reference potential to passive actuator electrodes. This can be desirable because it is often the case that suitable control units for controlling the actuator device, which may be implemented for example by way of one or more ASICs (ASIC: application-specific integrated circuit), are not able to provide sufficiently high voltages. However, high voltages can be desirable because they can help make it possible for example also to compensate for high spring stiffnesses of a flexure that is used and/or to achieve greater deflections of the mirror element. For example, cross sections of springs of the flexure may thus be made larger, which reduces the thermal resistance of the springs, which in turn leads to better heat dissipation and lower mirror temperatures when illuminating the mirror element of an optical component according to the disclosure. This also can help make it possible to reduce electrical resistance, and any photocurrents that may occur during illumination may thus be minimized.

Electrostatic softening may also be amplified in a targeted manner by applying different potentials for the passive actuator electrodes of different optical components of an optical apparatus according to the disclosure, such that production-related fluctuations in the spring stiffness of the springs are able to be compensated for. Electrostatic softening in the context of this disclosure should be understood to mean an angle-dependent modification of a spring constant of a resetting spring by applying an additional voltage to electrodes of an optical component.

### BRIEF DESCRIPTION OF THE DRAWINGS

Certain embodiments of the disclosure are explained in more detail with reference to the drawings and the following description. In the drawings:

FIG. 1 shows a side view of an optical component according to the disclosure; and

FIG. 2 shows a schematic sectional illustration of the optical component according to FIG. 1.

### Embodiments of the Disclosure

In the following description of certain embodiments of the disclosure, identical or similar elements are designated with the same reference signs, a repeated description of these elements in individual cases being omitted. The figures illustrate the subject matter of the disclosure only schematically.

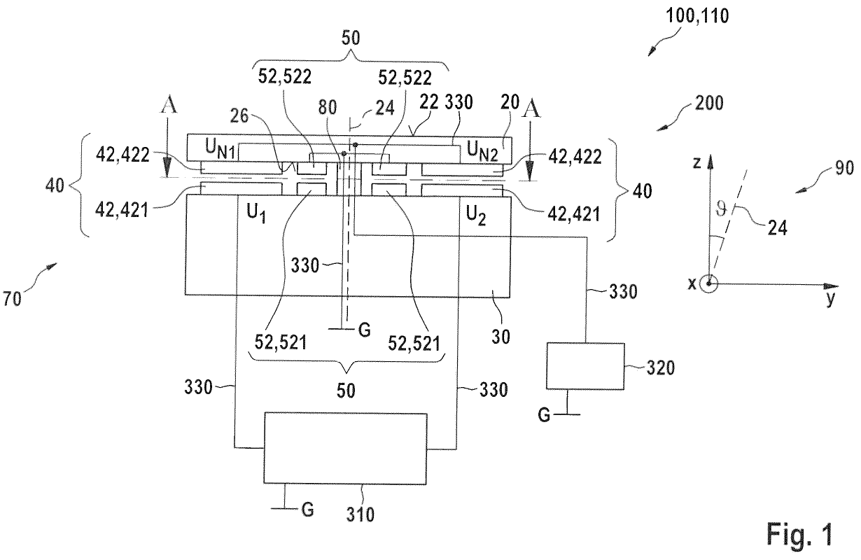

FIG. 1 shows a side view of an optical component 100 according to the disclosure, which is configured to carry out the method according to the disclosure, and also a connected control unit 310 and a voltage source 320. The optical component 100, together with the control unit 310 and the voltage source 320, constitutes an optical apparatus 110 according to the disclosure.

The optical component 100 in this case comprises a mirror element 20 and a substrate 30 for carrying the mirror element 20. The mirror element 20 is in this case mounted on an articulation device 80. To displace the mirror element 20, the optical component 100 comprises a displacement device 200, which has an actuator device 40 for tilting the mirror element 20 and a sensor device 50 for detecting a tilt angle 9 of the mirror element 20.

The optical component 100 is arranged, for illustrative purposes, in a three-dimensional Cartesian coordinate system 90. The three-dimensional Cartesian coordinate system 90 comprises an x-axis, a y-axis and a z-axis. The x-axis runs perpendicular to the plane of the drawing towards the observer in FIG. 1. The y-axis runs to the right in FIG. 1. The z-axis runs upwards in FIG. 1.

The mirror element 20 comprises a reflection surface 22 having a surface normal 24 that is perpendicular to the reflection surface 22. Here in the left-hand illustration in FIG. 1, the mirror element 20 is in an unpivoted or untilted state.

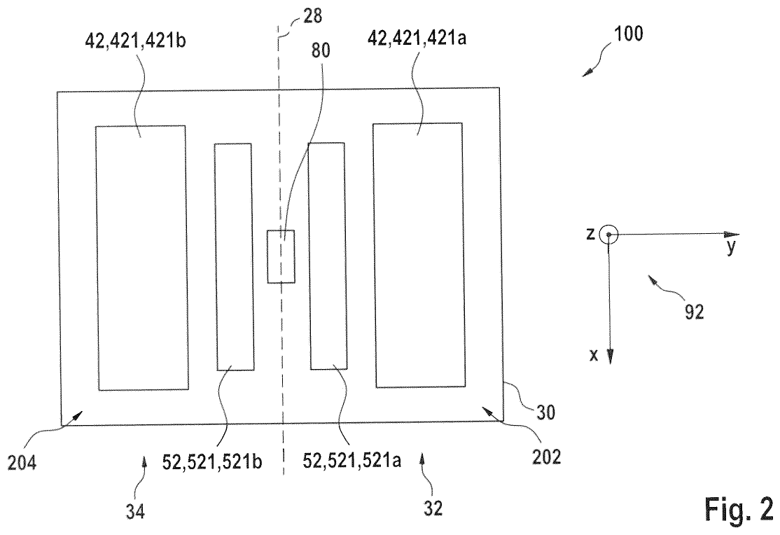

In this case, the substrate 30 is arranged on an x-y plane 92 (cf. FIG. 2), which is defined by the x-axis and the y-axis. In a tilted state, an angle is formed between the surface normal 24 and the z-axis in its running direction, which angle is defined as the tilt angle 9 of the mirror element 20 and is illustrated in the right-hand illustration in FIG. 1. This angle is also referred to as polar angle in a spherical coordinate system. The mirror element 20 may in this case be tilted about the x-axis. Of course, the mirror element 20 may also be tilted about the y-axis. The mirror element 20 may likewise be tilted simultaneously about the x-axis and y-axis in order to achieve an azimuth-dependent tilt angle 9.

The actuator device 40 in this case comprises an actuator electrode structure 42 having two active actuator electrodes 421 (cf. FIG. 2), which here are in the form of actuator stator electrodes and are attached to the substrate 30. The actuator electrode structure 42 in this case has two passive actuator electrodes 422 (cf. FIG. 2), which here are in the form of an actuator mirror electrode and are attached to a surface 26 of the mirror element 20 that faces away from the reflection surface 22. In FIG. 1 here, the passive actuator electrodes 422 are each assigned to an active actuator electrode 421. However, the actuator electrode structure 42 may also have a single passive actuator electrode 422 or more than two passive actuator electrodes 422.

The actuator electrodes 421, 422 are configured to exert electrostatic force. They can be in the form of comb electrodes. The active actuator electrodes 421 and the passive actuator electrodes 422 in this case can each comprise multiple comb fingers. FIG. 1 reveals that all of the active actuator electrodes 421 are arranged in a common plane 70, which is parallel to the x-y plane 92 and is also referred to as an actuator plane. The actuator device 40, respectively the active actuator electrodes 421 and the passive actuator electrodes 422, in this case form a direct drive for tilting the mirror element 20.

The sensor device 50 in this case comprises a sensor electrode structure 52. It may be seen in FIG. 1 that the sensor electrode structure 52 has two active sensor electrodes 521 (cf. FIG. 2) and two passive sensor electrodes 522 (cf. FIG. 2). In this case, the active sensor electrodes 521 are in the form of sensor stator electrodes and are attached to the substrate 30. It may also be seen in FIG. 1 that the active sensor electrodes 521 are likewise arranged in the common plane 70. The passive sensor electrodes 522 are in this case in the form of sensor mirror electrodes and are attached to the surface 26 of the mirror element 20 that faces away from the reflection surface 22. The sensor electrodes 521, 522 can be in the form of comb electrodes. The active sensor electrodes 521 and the passive sensor electrodes 522 in this case can each comprise multiple comb fingers.

FIG. 1 reveals that the articulation device 80 for mounting the mirror element 20 is arranged centrally. It may be in the form of a flexure, such as for example a gimbal flexure. This articulation device 80 defines a mechanical tilt axis 28 (see FIG. 2) of the mirror element 20. Optionally, the articulation device 80 defines two mechanical tilt axes 28 that intersect at a central point, which is also referred to as tilt point of the mirror element 20. This tilt point is located for example on the surface normal 24 through a central point of the mirror element 20 in the untilted state.

The control unit 310, for example an ASIC, is designed to apply potentials U₁, respectively U₂, to the active actuator electrodes 421 and to control them, for example to regulate them. By virtue of the voltage source 320, potentials U_{N1} and U_{N2} may be applied to the passive actuator electrodes 422 to the left (first portion of the passive actuator electrodes) and to the right (second portion of the passive actuator electrodes) of the surface normal 24. This can help enable significantly higher voltages between the passive actuator electrodes 422 and the active actuator electrodes 421. Optionally, U_{N1} and U_{N2} are identical, and so a common potential U_{N}=U_{N1}=U_{N2} is involved. Both the control unit 310 and the voltage source 320 are connected to a common reference potential G. The same applies to the passive sensor electrodes 522. The control unit 310 may furthermore be designed to control and/or to read out the active sensor electrodes 521.

FIG. 2 shows a schematic sectional illustration of the optical component 100 according to FIG. 1 along a sectional plane A in order to illustrate further aspects of the actuator and sensor device 40, 50.

The optical component 100 in FIG. 2 here is arranged in the three-dimensional Cartesian coordinate system 90. The x-axis runs downwards in FIG. 2. The y-axis runs to the right in FIG. 2. The z-axis runs perpendicular to the plane of the drawing towards the observer in FIG. 2. The substrate 30 is in this case arranged on the x-y-plane 92. The common plane 70 is in this case parallel to the x-y plane 92.

As illustrated in FIG. 2, the actuator device 40 or the actuator electrode structure 42 comprises two active actuator electrodes 421, which are arranged on the substrate 30. The sensor device 50 or the sensor electrode structure 52 in this case comprises two active sensor electrodes 521, which are in the form of sensor stator electrodes and are arranged on the substrate 30. All of the actuator and sensor stator electrodes 421, 521 are in this case arranged in the common plane 70.

FIG. 2 reveals that the articulation device 80 defines a tilt axis 28 of the mirror element 20, which tilt axis is aligned parallel to the common plane 70 and corresponds to the x-axis. In FIG. 2 here, the common plane 70 is divided into two sectors by the tilt axis 28, specifically a first sector 32 and a second sector 34. An active actuator electrode 421 and an active sensor electrode 521 are arranged in each sector 32, 34. Each active sensor electrode 521 is assigned to an active actuator electrode 421 in the same sector 32, 34.

The tilt axis 28 thus divides the active actuator and sensor electrodes 421, 521 into two electrode pairs 202, 204, which are each arranged in a sector 32, 34. A first electrode pair 202 in this case comprises an active actuator electrode 421a in the first sector 32 and an active sensor electrode 521a in the first sector 32, while a second electrode pair 204 comprises an active actuator electrode 421b in the second sector 34 and an active sensor electrode 521b in the second sector 34. It may also be seen in FIG. 2 that the first and the second electrode pair 202, 204 are arranged symmetrically with respect to the tilt axis 28. The active sensor electrode 521 and the active actuator electrode 421 are arranged going outwards, in that order, from the tilt axis 28 or the articulation device 80 in the respective sector 32, 34. A different order of the arrangement of the active actuator and sensor electrodes 421, 521 is also possible.

The passive actuator and sensor electrodes 422, 522 not illustrated in FIG. 2 are likewise distributed accordingly.

During operation of the optical component 100 according to FIGS. 1 and 2 with a method according to the disclosure, one or more potentials U_{N1}, U_{N2}, optionally a common potential U_{N}, may be applied to the one or more passive actuator electrodes 422, as illustrated, which common potential is generated by the voltage source 320 and is different from the common reference potential G to which both the voltage source 320 and the control unit 310 and the passive sensor electrodes 522 are connected. The potentials are provided via electrical connections 330 for the electrodes 421, 422, 522 of the optical component 100. A single line marked with the reference sign 330 in the figure in this case symbolizes, only purely schematically, the profile of the electrical connections 330 from the respective voltage source 310, 320 to an electrode 421, 422, 522, and may also correspond here to multiple physical electrical connections 330. This may be the case for example when different potentials U_{N1}, U_{N2} are applied to the two passive actuator electrodes 422 in the two sectors 32, 34, as shown in FIG. 1. There may also be electrical connections (not shown) between the control unit 310 and the active sensor electrodes 521, which electrical connections are used to control and/or read out the corresponding active sensor electrodes 521.

The disclosure is not limited to the exemplary embodiments described here and the aspects highlighted therein. On the contrary, a large number of modifications that are within the ability of a person skilled in the art are possible within the scope specified by the claims.

What is claimed is:

1. A method of operating an optical component comprising a mirror element, a substrate supporting the mirror element, an actuator device configured to tilt the mirror element about one or two tilt axes, and a sensor device, the actuator device comprising a plurality of active actuator electrodes and one or more passive actuator electrodes, the sensor device comprising a sensor electrode structure configured to detect a tilt angle of the mirror element based on changes in capacitance, the sensor device comprising a plurality of active sensor electrodes and a plurality of passive sensor electrodes, the method comprising:
generating a first voltage between a first portion of the active actuator electrodes and the one or more passive actuator electrodes; and
generating a second voltage between a second portion of the active actuator electrodes and the one or more passive actuator electrodes,
wherein the method further comprises, when the first voltage exceeds a first limit value and/or the second voltage exceeds a second limit value, applying a respective potential different from a reference potential to the one or more passive actuator electrodes via a voltage source with the reference potential.

2. The method of claim 1, wherein the respective potentials applied to the one or more passive actuator electrodes are identical.

3. The method of claim 1, wherein the respective potentials applied to the one or more passive actuator electrodes are different from a second potential of the passive sensor electrodes.

4. The method of claim 3, wherein each of the passive sensor electrodes has the reference potential.

5. The method of claim 1, further comprising changing one of the potentials applied to the one or more passive actuator electrodes when the first voltage exceeds a third limit value and/or the second voltage exceeds a fourth limit value.

6. The method of claim 1, further comprising regulating one of the potentials applied to the one or more passive actuator electrodes.

7. The method of claim 1, comprising, when the first voltage exceeds the first limit value, applying a respective potential different from a reference potential to the one or more passive actuator electrodes via a voltage source with the reference potential.

8. The method of claim 7, comprising, when the second voltage exceeds the second limit value applying a respective potential different from a reference potential to the one or more passive actuator electrodes via a voltage source with the reference potential.

9. The method of claim 1, wherein the respective potentials applied to the one or more passive actuator electrodes are identical, and the respective potentials applied to the one or more passive actuator electrodes are different from a second potential of the passive sensor electrodes.

10. The method of claim 9, further comprising changing one of the potentials applied to the one or more passive actuator electrodes when the first voltage exceeds a third limit value and/or the second voltage exceeds a fourth limit value.

11. The method of claim 10, further comprising regulating one of the potentials applied to the one or more passive actuator electrodes.

12. The method of claim 11, comprising, when the first voltage exceeds the first limit value, applying a respective potential different from a reference potential to the one or more passive actuator electrodes via a voltage source with the reference potential.

13. The method of claim 1, comprising, when the second voltage exceeds the second limit value applying a respective potential different from a reference potential to the one or more passive actuator electrodes via a voltage source with the reference potential.

14. One or more machine-readable hardware storage devices comprising instructions that are executable by one or more processing devices to perform operations comprising the method of claim 1.

15. A system, comprising:
one or more processing devices; and
one or more machine-readable hardware storage devices comprising instructions that are executable by one or more processing devices to perform operations comprising the method of claim 1.

16. An optical apparatus, comprising:
an optical component, comprising:
a mirror element;
a substrate supporting the mirror element;
an actuator device configured to tilt the mirror element about one or two tilt axes, the actuator device comprising a plurality of active actuator electrodes and one or more passive actuator electrodes; and
a sensor device comprising a sensor electrode structure configured to detect a tilt angle of the mirror element based on changes in capacitance, the sensor device comprising a plurality of active sensor electrodes and a plurality of passive sensor electrodes;
a voltage source; and
a controller,
wherein:
the control unit and the voltage source are connected to a common reference potential;
the control unit is configured to control the voltage source to:
generate a first voltage between a first portion of the active actuator electrodes and the one or more passive actuator electrodes;
generate a second voltage between a second portion of the active actuator electrodes and the one or more passive actuator electrodes; and
when the first voltage exceeds a first limit value and/or the second voltage exceeds a second limit value, apply a respective potential different from a reference potential to the one or more passive actuator electrodes.

17. An optical unit, comprising:
an optical system according to claim 16,
wherein the illumination optical unit is configured to be used in a projection exposure apparatus to guide illumination radiation to an object field.

18. An illumination system, comprising:
a radiation source; and
an illumination optical unit configured to be used in a projection exposure apparatus to guide illumination radiation to an object field,
wherein the illumination optical unit comprises an optical system according to claim 16, and the illumination system is configured to be used in a projection exposure apparatus.

19. An apparatus, comprising:
an illumination system, comprising:
a radiation source;
an illumination optical unit configured to be used in a projection exposure apparatus to guide illumination radiation to an object field; and
a projection optical unit configured to project an object in the object field into an image field,
wherein the illumination optical unit comprises an optical system according to claim 16, and the apparatus is a microlithographic projection exposure apparatus.

20. A method of using a microlithographic projection exposure apparatus comprising an illumination optical unit and a projection optical unit, the method comprising:
using the illumination optical unit to at least partially illuminate an object in an object field of the projection optical unit; and
using the projection optical unit to project the at least partially illuminated object into an image field,
wherein the illumination optical unit comprises an optical system according to claim 16.
